(19) United States
(12) Patent Application Publication
(10) Pub. No.: US 2022/0374062 A1
(43) Pub. Date: Nov. 24, 2022

(54) SYSTEM MANAGEMENT BUS LINK, METHOD AND APPARATUS FOR DETERMINING PULL-UP RESISTANCE THEREOF, AND DEVICE

(71) Applicant: INSPUR SUZHOU INTELLIGENT TECHNOLOGY CO., LTD., Suzhou (CN)

(72) Inventor: Yuanbin YUE, Suzhou (CN)

(21) Appl. No.: 17/755,532

(22) PCT Filed: Jan. 20, 2020
(86) PCT No.: PCT/CN2020/073117

§ 371 Date: Apr. 29, 2022

(30) Foreign Application Priority Data
Nov. 7, 2019 (CN) 201911082417.6

(51) Int. Cl. G06F 1/30

(52) U.S. Cl. CPC G06F 1/30

(57) ABSTRACT

A system management bus link, a method and apparatus for determining the pull-up resistance thereof, and a device. The system management bus link comprises: a motherboard chip, a first pull-up resistor, and a second pull-up resistor. In the present invention, when resistance values of the first pull-up resistor and the second pull-up resistor satisfy configuring on a system management bus link any number of PSU power supplies that is smaller than or equal to a number threshold, a clock line in the link and a drive current in a data line are between a 0.5-times drive current threshold and a 0.9-times drive current threshold. Thus, the pull-up resistance of a motherboard end is optimized, which reduces the effect on the drive capacity of the number of PSU power supplies on a link, guarantees the drive capacity of the link, and improves link stability.

### CROSS REFERENCE TO RELATED APPLICATIONS

This application is a 371 of International Patent Application Number PCT/CN2020/073117, filed on Jan. 20, 2020, which claims the benefit and priority of the Chinese patent application No. 201911082417.6, filed to the Patent Office of the People's Republic of China on Nov. 7, 2019 and entitled “System Management Bus Link, method and apparatus for determining pull-up resistance thereof, and device”, the entire contents of which are incorporated herein by reference.

### TECHNICAL FIELD

The disclosure relates to the technical field of data centers, in particular to a System Management Bus Link, method and apparatus for determining pull-up resistance thereof.

### BACKGROUND

With the continuous development of science and technology, the era of big data, cloud computing and artificial intelligence based on the Internet has arrived. The amount of Internet data has increased dramatically. Accordingly, the amount of calculation and the frequency of calculation have increased, and the number of servers in a data center is also increasing. The total power consumption of each rack location in the data center is definite. If the total power consumption limit is exceeded, protection will be triggered. The total power consumption determines the number of servers that can be placed in a rack location. For each server, the overall power consumption information of the server is monitored in real time. This puts forward higher requirements for power management on a motherboard of the server.

In the prior art, a power supply unit (PSU) power supply is often used to supply power to the server. In general cases, one PSU power supply (namely, PSU module) can meet the power supply requirements of one rack-mounted server. However, a redundancy design of two PSU power supplies is used currently. When one of the PSU power supplies fails unpredictably, the other PSU power supply can continue to ensure the normal operation of the server. In the power consumption monitoring process of the PSU power supply, first, a management engine (ME) on the server motherboard reads power consumption information of the PSU power supply through a system management bus (SMBUS), then a baseboard management controller (BMC) reads information of the PSU power supply from the ME through another I2C bus to ensure real-time monitoring of the power supply and power consumption of the server. In this process, an SMBUS link should have enough driving capacity to ensure that signals can be transmitted normally when reading the information of the PSU power supply. If the driving capacity is not enough, abnormal data will occur in the signal transmission process, and the power consumption cannot be monitored normally.

Therefore, how to reduce the influence of the number of PSU power supplies on the system management bus (SMBUS) link on the driving capacity, ensure the driving capacity of the system management bus link, avoid the abnormal data in the signal transmission process and improve the stability of the link is an urgent problem to be solved.

### SUMMARY

An objective of the disclosure is to provide a System Management Bus Link, method and apparatus for determining pull-up resistance thereof. Pull-up resistors on a motherboard side are optimized to reduce the influence of the number of PSU power supplies on the link on the driving capacity, ensure the driving capacity of the link and improve the stability of the link.

In order to solve the above technical problem, the disclosure provides a system management bus link, including: a motherboard chip, a first pull-up resistor and a second pull-up resistor.

First ends of the first pull-up resistor and the second pull-up resistor are connected to an output end of a driving voltage, a second end of the first pull-up resistor is connected to a clock end of the motherboard chip, a common end where the second end of the first pull-up resistor is connected to the clock end of the motherboard chip is configured to be connected to clock ends of a number of PSU power supply chips that is less than or equal to a number threshold, a second end of the second pull-up resistor is connected to a data end of the motherboard chip, and a common end where the second end of the second pull-up resistor is connected to the data end of the motherboard chip is configured to be connected to data ends of the PSU power supply chips. The clock end of each of the PSU power supply chips is connected to a second end of a corresponding third pull-up resistor in one-to-one correspondence, and the data end of each of the PSU power supply chips is connected to a second end of a corresponding fourth pull-up resistor in one-to-one correspondence. First ends of the third pull-up resistor and the fourth pull-up resistor are connected to the output end of the driving voltage.

The number threshold is a positive integer greater than 2. A resistance value of the first pull-up resistor satisfies that when the clock end of the motherboard chip is connected to the clock ends of any number of the PSU power supply chips, a driving current between the clock end of the motherboard chip and the clock end of each of the PSU power supply chips is greater than or equal to 0.5n and less than or equal to 0.9n. A resistance value of the second pull-up resistor satisfies that when the data end of the motherboard chip is connected to the data ends of any number of the PSU power supply chips, a driving current between the data end of the motherboard chip and the data end of each of the PSU power supply chips is greater than or equal to 0.5n and less than or equal to 0.9n. n is a driving current threshold.

Optionally, the number threshold is 4.

Optionally, when resistance values of the third pull-up resistors are all 20 KΩ the resistance value of the first pull-up resistor is 1.9 KΩ.

Optionally, the system management bus link further includes: a preset number of the PSU power supply chips, the third pull-up resistors and the fourth pull-up resistors.

The preset number is less than or equal to the number threshold.

Optionally, the system management bus link further includes: a first MOS transistor, a second MOS transistor, a first resistor and a second resistor.

The common end where the second end of the first pull-up resistor is connected to the clock end of the motherboard chip is connected to a drain of the first MOS transistor, a source of the first MOS transistor is connected to the clock end of the PSU power supply chip, a gate of the first MOS transistor is connected to a first end of the first resistor, and a second end of the first resistor is connected to the output end of the driving voltage. The common end where the second end of the second pull-up resistor is connected to the data end of the motherboard chip is connected to a drain of the second MOS transistor, a source of the second MOS transistor is configured to be connected to the data end of the PSU power supply chip, a gate of the second MOS transistor is connected to a first end of the second resistor, and a second end of the second resistor is connected to the output end of the driving voltage.

The disclosure further provides a method for determining pull-up resistance of a system management bus link, including:

acquiring pull-up resistance combinations; where each of the pull-up resistance combinations includes a PSU pull-up resistor resistance value and one motherboard pull-up resistor resistance value;

calculating an equivalent resistance range corresponding to a preset driving current range according to an acquired driving voltage; where the preset driving current range is greater than or equal to 0.5n and less than or equal to 0.9n, and n is a driving current threshold;

determining whether there is a target pull-up resistance combination in the pull-up resistance combinations; where a parallel equivalent resistance of any number of PSU pull-up resistors that is less than or equal to a number threshold and a motherboard pull-up resistor corresponding to each of the target pull-up resistance combinations is within the equivalent resistance range; and

outputting, if there is the target pull-up resistance combination, the target pull-up resistance combination.

Optionally, the motherboard pull-up resistor resistance value in each of the target pull-up resistance combinations is less than or equal to 0.5 times the equivalent resistance of the corresponding any number of PSU pull-up resistors that is less than or equal to the number threshold.

Optionally, when each of the pull-up resistance combinations includes the PSU pull-up resistor resistance value and the motherboard pull-up resistor resistance value, outputting the target pull-up resistance combination includes:

calculating a quotient of the PSU pull-up resistor resistance value and the motherboard pull-up resistor resistance value in each of the target pull-up resistance combinations, and outputting the target pull-up resistance combination corresponding to the quotient with the largest value.

The disclosure further provides an apparatus for determining pull-up resistance of a system management bus link, including:

an acquisition module, configured to acquire pull-up resistance combinations; where each of the pull-up resistance combinations includes a PSU pull-up resistor resistance value and one motherboard pull-up resistor resistance value;

a calculation module, configured to calculate an equivalent resistance range corresponding to a preset driving current range according to an acquired driving voltage; where the preset driving current range is greater than or equal to 0.5n and less than or equal to 0.9n, and n is a driving current threshold;

a determination module, configured to determine whether there is a target pull-up resistance combination in the pull-up resistance combinations; where a parallel equivalent resistance of any number of PSU pull-up resistors that is less than or equal to a number threshold and a motherboard pull-up resistor corresponding to each of the target pull-up resistance combinations is within the equivalent resistance range; and

an output module, configured to output, if there is the target pull-up resistance combination, the target pull-up resistance combination.

The disclosure further provides a device for determining pull-up resistance of a system management bus link, including:

a memory, configured to store a computer program; and

a processor, configured to implement the steps of any method for determining pull-up resistance of a system management bus link when executing the computer program.

According to the system management bus link provided by the disclosure, the resistance values of the first pull-up resistor and the second pull-up resistor satisfy that when any number of PSU power supplies that is less than or equal to the number threshold are configured on the system management bus link, the driving currents in the clock line and the data line in the link are both between 0.5 times the driving current threshold and 0.9 times the driving current threshold, so that the pull-up resistors on the motherboard side are optimized, thereby reducing the influence of the number of PSU power supplies on the link on the driving capacity, ensuring the driving capacity of the link and improving the stability of the link. In addition, the disclosure further provides a method, apparatus and device for determining pull-up resistance of a system management bus link, which also have the above beneficial effects.

### BRIEF DESCRIPTION OF THE DRAWINGS

In order to more clearly illustrate the embodiments of the disclosure or the technical solutions in the prior art, the accompanying drawings used in the description of the embodiments or the prior art will be briefly described below. Apparently, the accompanying drawings in the following description are only some embodiments of the disclosure, and those skilled in the art can obtain other drawings according to the provided drawings without any creative work.

FIG. 1 is a schematic structural diagram of a system management bus link according to an embodiment of the disclosure;

FIG. 2 is a schematic circuit diagram of a system management bus link in the prior art;

FIG. 3 is a schematic circuit diagram of another system management bus link according to an embodiment of the disclosure;

FIG. 4 is a flow chart of a method for determining pull-up resistance of a system management bus link according to an embodiment of the disclosure; and

FIG. 5 is a structural block diagram of an apparatus for determining pull-up resistance of a system management bus link according to an embodiment of the disclosure.

### DETAILED DESCRIPTION

In order to clearly describe objectives, the technical solutions and advantages of the embodiments of the disclosure, a clear and complete description of the technical solutions in the embodiments of the disclosure will be given below, in conjunction with the accompanying drawings in the embodiments of the disclosure. Apparently, the embodiments described below are a part, but not all, of the embodiments of the disclosure. All other embodiments obtained by those of ordinary skill in the art based on the embodiments of the disclosure without creative work are within the protection scope of the disclosure.

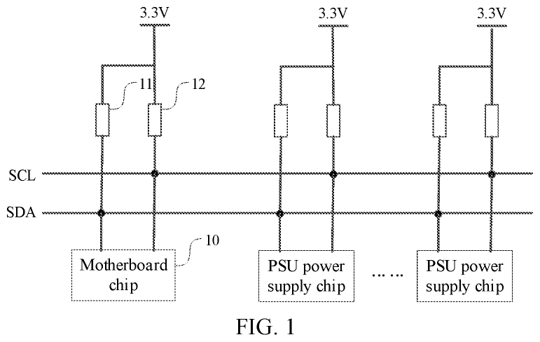

Referring to FIG. 1, FIG. 1 is a schematic structural diagram of a system management bus link according to an embodiment of the disclosure. The link may include: a motherboard chip 10, a first pull-up resistor 11 and a second pull-up resistor 12.

First ends of the first pull-up resistor 11 and the second pull-up resistor 12 are connected to an output end of a driving voltage. A second end of the first pull-up resistor 11 is connected to a clock end of the motherboard chip 10. A common end where the second end of the first pull-up resistor 11 is connected to the clock end of the motherboard chip 10 is configured to be connected to clock ends of a number of PSU power supply chips that is less than or equal to a number threshold. A second end of the second pull-up resistor 12 is connected to a data end of the motherboard chip 10. A common end where the second end of the second pull-up resistor 12 is connected to the data end of the motherboard chip 10 is configured to be connected to data ends of the PSU power supply chips. The clock end of each of the PSU power supply chips is connected to a second end of a corresponding third pull-up resistor in one-to-one correspondence, and the data end of each of the PSU power supply chips is connected to a second end of a corresponding fourth pull-up resistor in one-to-one correspondence. First ends of the third pull-up resistor and the fourth pull-up resistor are connected to the output end of the driving voltage.

The number threshold is a positive integer greater than 2. A resistance value of the first pull-up resistor 11 satisfies that when the clock end of the motherboard chip 10 is connected to the clock ends of any number of the PSU power supply chips, a driving current between the clock end of the motherboard chip 10 and the clock end of each of the PSU power supply chips is greater than or equal to 0.5n and less than or equal to 0.9n. A resistance value of the second pull-up resistor 12 satisfies that when the data end of the motherboard chip 10 is connected to the data ends of any number of the PSU power supply chips, a driving current between the data end of the motherboard chip 10 and the data end of each of the PSU power supply chips is greater than or equal to 0.5n and less than or equal to 0.9n. n is a driving current threshold.

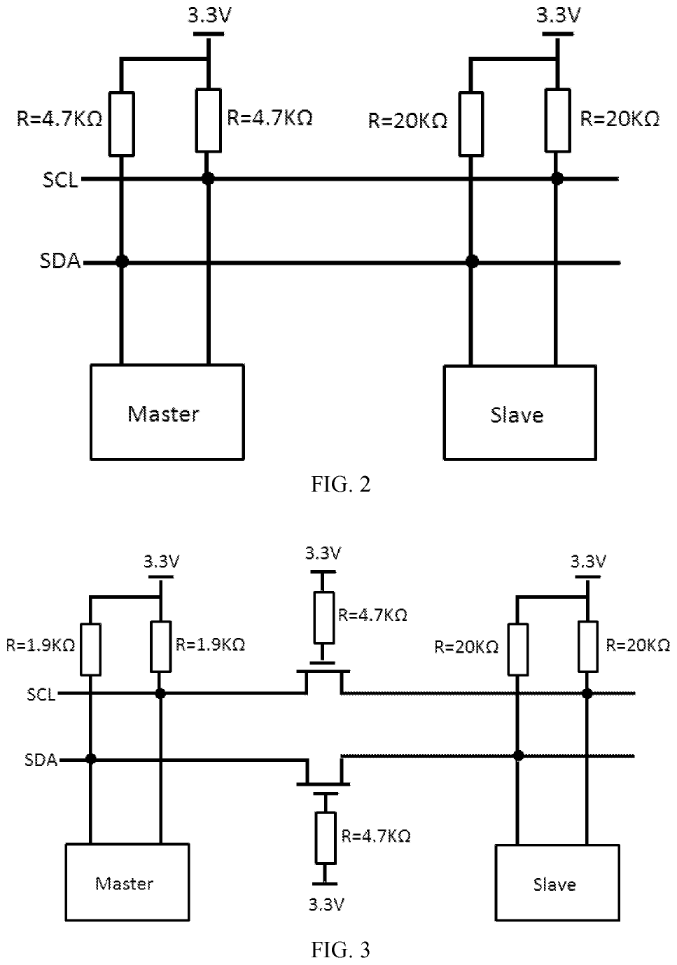

It should be noted that the first pull-up resistor 11 in this embodiment may be a pull-up resistor of the motherboard chip 10 on a clock line of a system management bus (SMBUS), for example, a 4.7 KΩ resistor (R) connected on the clock line (SCL) in FIG. 2 and a 1.9 KΩ resistor (R) connected on the clock line (SCL) in FIG. 3. The second pull-up resistor 12 in this embodiment may be a pull-up resistor of the motherboard chip 10 on a data line of the system management bus, for example, a 4.7 KΩ resistor (R) connected on the data line (SDA) in FIG. 2 and a 1.9 KΩ resistor (R) connected on the data line (SDA) in FIG. 3. The motherboard chip 10 in this embodiment may be a processor that is disposed on a motherboard of a server and used to read power consumption information of a PSU power supply through the SMBUS, that is, a management engine (ME) chip in the prior art, for example, Master in FIG. 2 and FIG. 3.

Correspondingly, since the SMBUS includes the clock line and the data line, when reading the power consumption information of the PSU power supply through the SMBUS, the motherboard chip 10 needs to be connected to the PSU power supply chip of the PSU power supply through the clock line and the data line of the SMBUS, that is, the clock end and the data end of the motherboard chip 10 are respectively connected to the clock end and the data end of the PSU power supply chip in one-to-one correspondence. That is to say, in this embodiment, the common end where the second end of the first pull-up resistor 11 is connected to the clock end of the motherboard chip 10 and the common end where the second end of the second pull-up resistor 12 is connected to the data end of the motherboard chip 10 may be connected to the same PSU power supply chip.

Specifically, the number threshold in this embodiment may be the maximum number of PSU power supplies that can be mounted on the SMBUS link, that is, the maximum number of PSU power supply chips that the motherboard chip 10 can be connected to through the SMBUS, for example, 4. In this embodiment, the motherboard chip 10, the first pull-up resistor 11 and the second pull-up resistor 12 may be disposed on the motherboard of the server. A signal when the motherboard chip 10 on the motherboard is connected to the PSU power supply chip of each of the PSU power supplies and configured to read information is a signal of the SMBUS, and apparatuses on the SMBUS are of wired-AND logic, so usually there are pull-up resistors in the apparatuses at both ends of the SMBUS, for example, the 1.9 KΩ resistors of Master connected on SCL and SDA and the 20 KΩ resistors (i.e. the third pull-up resistor and the fourth pull-up resistor) of Slave (PSU power supply chip) connected on SCL and SDA in FIG. 2.

In this embodiment, the resistance value of the pull-up resistor connected to the PSU power supply chip that is connected to the motherboard chip 10 through the SMBUS bus may be within a resistance value set, that is, the resistance values of the third pull-up resistor and the fourth pull-up resistor may be respectively within the corresponding preset resistance value set. That is to say, in this embodiment, the resistance values of the third pull-up resistor and the fourth pull-up resistor connected to each of the PSU power supply chips on the SMBUS link are definite. For example, since the resistance values of the third pull-up resistor and the fourth pull-up resistor corresponding to each of the PSU power supply chips are the same in the prior art, that is, the third pull-up resistor and the fourth pull-up resistor correspond to the same preset resistance value set, the preset resistance value set may only include one resistance value, that is, the resistance values of the pull-up resistors (i.e. the third pull-up resistors and the fourth pull-up resistors) connected to the number of PSU power supply chips that is less than or equal to the number threshold that can be connected on the SMBUS link may be the same, for example, 20 KΩ in FIG. 2. The preset resistance value set may include a plurality of resistance values, that is, the resistance values of the pull-up resistors (i.e. the third pull-up resistors and the fourth pull-up resistors) connected to the number of PSU power supply chips that is less than or equal to the number threshold that can be connected on the SMBUS link may be different. As long as the setting of the resistance values of the pull-up resistors (i.e. the first pull-up resistor 11 and the second pull-up resistor 12) connected to the motherboard chip 10 can satisfy that when any number of PSU power supplies that is less than or equal to the number threshold are configured on the SMBUS link, the driving currents in the clock line and the data line in the link are respectively between 0.5 times the driving current threshold and 0.9 times the driving current threshold, this embodiment does not impose any limitation on this.

It can be understood that in this embodiment, the resistance value of the first pull-up resistor 11 satisfies that when the clock end of the motherboard chip 10 is connected to the clock ends of any number of PSU power supply chips that is less than or equal to the number threshold, the driving current between the clock end of the motherboard chip 10 and the clock end of each of the PSU power supply chips is greater than or equal to 0.5 times the driving current threshold and less than or equal to 0.9 times the driving current threshold; the resistance value of the second pull-up resistor 12 satisfies that when the data end of the motherboard chip 10 is connected to the data ends of any number of PSU power supply chips that is less than or equal to the number threshold, the driving current between the data end of the motherboard chip 10 and the data end of each of the PSU power supply chips is greater than or equal to 0.5 times the driving current threshold and less than or equal to 0.9 times the driving current threshold; and thus, no matter how many PSU power supplies are mounted on the SMBUS, the driving current in the SMBUS is always between 0.5 times the driving current threshold and 0.9 times the driving current threshold. For example, when the driving current threshold is 3 mA required by the ME chip, the driving current in the SMBUS can be between 1.5 mA and 2.7 mA, thereby ensuring the driving capacity of the SMBUS link and improving the stability of the SMBUS link.

Specifically, the specific resistance values of the first pull-up resistor 11 and the second pull-up resistor 12 in this embodiment can be set by the designer according to the actual scenarios and user requirements. For example, if the number threshold is 4, when the resistance values of the pull-up resistors of each apparatus on the data line and the clock line in the SMBUS link are equal, that is, when the resistance values of the first pull-up resistor 11 and the second pull-up resistor 12 corresponding to the motherboard chip 10 are equal and the resistance values of the third pull-up resistor and the fourth pull-up resistor corresponding to each of the PSU power supply chips are equal, as shown in FIG. 3, when the resistance values of the third pull-up resistor and the fourth pull-up resistor corresponding to each of the PSU power supply chips are both 20 KΩ, the resistance values of the first pull-up resistor 11 and the fourth pull-up resistor may be both 1.9 KΩ. Thus, compared with the case in which the resistance values of the first pull-up resistor 11 and the fourth pull-up resistor are both 4.7 KΩ in FIG. 2, no matter how many PSU power supplies are paralleled on the SMBUS, the driving current can be significantly increased.

Correspondingly, in this embodiment, in order to satisfy the requirements of strong pull-up at the motherboard and weak pull-up at the PSU power supplies in the SMBUS link, the resistance value of the first pull-up resistor 11 may also satisfy that when the clock end of the motherboard chip 10 is connected to the clock ends of any number of PSU power supply chips that is less than or equal to the number threshold, the resistance value of the first pull-up resistor 11 is less than or equal to half of a parallel equivalent resistance corresponding to the connected third pull-up resistors; and the resistance value of the second pull-up resistor 12 may also satisfy that when the data end of the motherboard chip 10 is connected to the data ends of any number of PSU power supply chips that is less than or equal to the number threshold, the resistance value of the second pull-up resistor 12 is less than or equal to half of a parallel equivalent resistance corresponding to the connected fourth pull-up resistors.

Specifically, in this embodiment, in order to further reduce the influence of paralleling of the PSU power supplies on the driving current in the SMBUS link so as to make the value of the driving current in the SMBUS link constant, the resistance values of the first pull-up resistor 11 and the second pull-up resistor 12 in this embodiment may be the minimum value among the resistance values that satisfy the above requirements.

Further, in order to improve the signal quality of the SMBUS link and prevent false alarms caused by the quality of the signal waveform, MOS transistors may be added to the SMBUS link on the motherboard side in this embodiment to eliminate noise coupled to the SMBUS. As shown in FIG. 2 and FIG. 3, after the SMBUS link shown in FIG. 2 is optimized to obtain the SMBUS link shown in FIG. 3, the abnormal waveform caused by the driving capacity of the SMBUS link shown in FIG. 2 can be eliminated, so that the waveform of the driving current is more stable. For example, the system management bus link provided by this embodiment may further include: a first MOS transistor, a second MOS transistor, a first resistor and a second resistor. The common end where the second end of the first pull-up resistor 11 is connected to the clock end of the motherboard chip 10 is connected to a drain of the first MOS transistor, a source of the first MOS transistor is connected to the clock end of the PSU power supply chip, a gate of the first MOS transistor is connected to a first end of the first resistor, and a second end of the first resistor is connected to the output end of the driving voltage. The common end where the second end of the second pull-up resistor 12 is connected to the data end of the motherboard chip 10 is connected to a drain of the second MOS transistor, a source of the second MOS transistor is configured to be connected to the data end of the PSU power supply chip, a gate of the second MOS transistor is connected to a first end of the second resistor, and a second end of the second resistor is connected to the output end of the driving voltage.

That is to say, the common end where the second end of the first pull-up resistor 11 is connected to the clock end of the motherboard chip 10 is specifically configured to be connected to the clock ends of the number of PSU power supply chips that is less than or equal to the number threshold through the first MOS transistor. The common end where the second end of the second pull-up resistor 12 is connected to the data end of the motherboard chip 10 is specifically configured to be connected to the data ends of the number of PSU power supply chips that is less than or equal to the number threshold through the second MOS transistor.

Specifically, the system management bus link provided by this embodiment may further include: a preset number of the PSU power supply chips, the third pull-up resistors and the fourth pull-up resistors. The preset number is less than or equal to the number threshold. That is to say, the system management bus link in this embodiment may include not only the motherboard chip 10 and the pull-up resistors (i.e. the first pull-up resistor 11 and the second pull-up resistor 12) on the motherboard side, but also the PSU power supply chip and the pull-up resistors (i.e. the third pull-up resistor and the fourth pull-up resistor) on each PSU power supply side.

In this embodiment of the disclosure, the resistance values of the first pull-up resistor 11 and the second pull-up resistor 12 satisfy that when any number of PSU power supplies that is less than or equal to the number threshold are configured on the system management bus link, the driving currents in the clock line and the data line in the link are both between 0.5 times the driving current threshold and 0.9 times the driving current threshold, so that the pull-up resistors on the motherboard side are optimized, thereby reducing the influence of the number of PSU power supplies on the link on the driving capacity, ensuring the driving capacity of the link and improving the stability of the link.

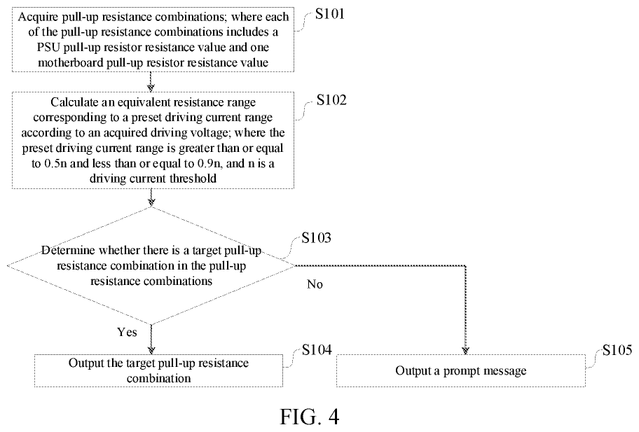

Referring to FIG. 4, FIG. 4 is a flow chart of a method for determining pull-up resistance of a system management bus link according to an embodiment of the disclosure. The method may include:

Step 101: Pull-up resistance combinations are acquired. Each of the pull-up resistance combinations includes a PSU pull-up resistor resistance value and one motherboard pull-up resistor resistance value.

It can be understood that the method for determining pull-up resistance of the system management bus (SMBUS) link in this embodiment may be a method for determining resistance value of a motherboard pull-up resistor and a PSU pull-up resistor on any of a data line and a clock line in the SMBUS link. For example, the resistance values of the two pull-up resistors corresponding to each apparatus on the SMBUS link may be different, that is, resistance values of a first pull-up resistor and a second pull-up resistor may be different. When the resistance values of the two pull-up resistors corresponding to each apparatus on the SMBUS link are the same, the method provided by this embodiment may be the method for determining resistance value of the motherboard pull-up resistor and the PSU pull-up resistor on the data line and the clock line in the SMBUS link.

Specifically, each of the pull-up resistance combinations in this step may include a resistance value of one motherboard pull-up resistor (i.e. motherboard pull-up resistor resistance value) and a resistance value or resistance values of one or a plurality of PSU pull-up resistors (i.e. PSU pull-up resistor resistance values). That is, when the resistance values of the two pull-up resistors corresponding to each apparatus on the SMBUS link are the same, the resistance value of the pull-up resistors on the motherboard side (i.e. the first pull-up resistor and the second pull-up resistor) in the SMBUS link in one pull-up resistance combination is used as the motherboard pull-up resistor resistance value in the pull-up resistance combination, and the resistance values of the pull-up resistors on each PSU power supply side (i.e. the third pull-up resistor and the fourth pull-up resistor) in the SMBUS link are both one PSU pull-up resistor resistance value in the pull-up resistance combination. For example, when there is only one PSU pull-up resistor resistance value in the pull-up resistance combination, the resistance values of the pull-up resistors on the plurality of PSU power supply sides in the SMBUS link are all equal. When there are a plurality of PSU pull-up resistor resistance values in the pull-up resistance combination, the resistance values of the pull-up resistors on the plurality of PSU power supply sides in the SMBUS link may not be equal.

It should be noted that specific acquisition manners of the pull-up resistance combinations in this step can be set by the designer according to the actual scenarios and user requirements. For example, a pull-up resistance combination input by a user can be received directly. Alternately, a corresponding pull-up resistance combination is automatically generated according to a PSU pull-up resistor resistance value and a motherboard pull-up resistor resistance value input by the user. If each of the pull-up resistance combinations includes one PSU pull-up resistor resistance value and one motherboard pull-up resistor resistance value, each motherboard pull-up resistor resistance value and different PSU pull-up resistor resistance values input by the user can be combined to generate the corresponding pull-up resistance combinations. For example, when the user inputs two motherboard pull-up resistor resistance values 1.9 KΩ and 4.7 KΩ and two PSU pull-up resistor resistance values 10 KΩ and 20 KΩ, four pull-up resistance combinations, namely 4.7 KΩ+20 KΩ, 1.9 KΩ+10 KΩ, 4.7 KΩ+10 KΩ and 1.9KΩ+20 KΩ, can be automatically generated.

Step 102: An equivalent resistance range corresponding to a preset driving current range is calculated according to an acquired driving voltage. The preset driving current range is greater than or equal to 0.5n and less than or equal to 0.9n. n is a driving current threshold.

It can be understood that the purpose of this step may be to calculate the equivalent resistance range corresponding to the preset driving current range by using the preset driving voltage (for example, 3.3V in FIG. 2 and FIG. 3) of the SMBUS link, that is, an equivalent resistance range on the SMBUS link that makes the driving current on the SMBUS link be between 0.5 times the driving current threshold and 0.9 times the driving current threshold.

It should be noted that this step and step 101 do not have a logically necessary sequence. Step 101 may be performed before this step as shown in this embodiment, or step 101 may be performed after this step, or the two steps may be performed at the same time, which is not limited in this embodiment.

Step 103: Whether there is a target pull-up resistance combination in the pull-up resistance combinations is determined. If there is the target pull-up resistance combination, the process goes to step 104.

A parallel equivalent resistance of any number of PSU pull-up resistors that is less than or equal to a number threshold and a motherboard pull-up resistor corresponding to each of the target pull-up resistance combinations is within the equivalent resistance range.

It can be understood that the resistance value of each of the PSU pull-up resistors corresponding to the target pull-up resistance combination in this step may be one of the PSU pull-up resistor resistance values in the target pull-up resistance combination, and the resistance value of the motherboard pull-up resistor corresponding to the target pull-up resistance combination may be the motherboard pull-up resistor resistance value in the target pull-up resistance combination.

Correspondingly, the purpose of this step may be to determine whether there is a pull-up resistance combination (that is, the target pull-up resistance combination) in the pull-up resistance combinations that makes a parallel equivalent resistance corresponding to one motherboard pull-up resistor and any number of PSU pull-up resistors that is less than or equal to the number threshold be within the equivalent resistance range by determining whether there is the target pull-up resistance combination in the pull-up resistance combinations, so that in the SMBUS link using the target pull-up resistance combination, as long as the number of PSU power supplies connected is less than or equal to the number threshold, the driving current of the SMBUS link is between 0.5 times the driving current threshold and 0.9 times the driving current threshold.

Further, since strong pull-up at the motherboard and weak pull-up at the PSU power supplies are required in the SMBUS link, this embodiment may require that: in the SMBUS link using the target pull-up resistance combination, as long as the number of PSU power supplies connected is less than or equal to the number threshold, the resistance value of the motherboard pull-up resistor in the SMBUS link is less than or equal to 0.5 times the equivalent resistance of the PSU pull-up resistors in the SMBUS link, so that the equivalent resistance of the parallel PSU pull-up resistors in the SMBUS link is much greater than the resistance value of the motherboard pull-up resistor, thereby satisfying the requirements of strong pull-up at the motherboard and weak pull-up at the PSU power supplies. That is to say, in this embodiment, the motherboard pull-up resistor resistance value in each of the target pull-up resistance combinations is less than or equal to 0.5 times the equivalent resistance of corresponding any number of PSU pull-up resistors that is less than or equal to the number threshold.

Specifically, when the number threshold is 4 and the driving current threshold is 3 mA, taking the four pull-up resistance combinations, namely 4.7 KΩ+20 KΩ, 1.9 KΩ+10 KΩ, 4.7 KΩ+10 KΩ and 1.9 KΩ+20 KΩ, shown in Table 1 as an example, the overall driving current of the pull-up resistance combination 4.7 KΩ+20 KΩ is small, and the maximum driving current is 1.238 mA which is less than the median of 3 mA, i.e., 1.5 mA, so this pull-up resistance combination is not the target pull-up resistance combination. As for the pull-up resistance combination 1.9 KΩ+10 KΩ, when 4 driving power supplies are paralleled, the driving current is 2.78 mA which is greater than 2.7 mA (0.9 times the driving current threshold), and moreover, when 4 driving power supplies are paralleled, the equivalent resistance of the 4 10 KΩ PSU pull-up resistors is 2.5 KΩ which is close to the resistance value 1.9 KΩ of the motherboard pull-up resistor, which thereby fails to well satisfy the requirements of strong pull-up at the motherboard and weak pull-up at the PSU power supplies, so this pull-up resistance combination is not the target pull-up resistance combination. As for the pull-up resistance combination 4.7 KΩ+10 KΩ, in the cases where there is 1 driving power supply and two driving power supplies paralleled, the driving current is less than 1.5 mA, and moreover, when 4 driving power supplies are paralleled, the equivalent resistance of the 4 10 KΩ PSU pull-up resistors is 2.5 KΩ which is less than the resistance value 1.9 KΩ of the motherboard pull-up resistor, which thereby leads to weak pull-up at the motherboard and strong pull-up at the PSU power supplies, so this pull-up resistance combination is not the target pull-up resistance combination. As for the pull-up resistance combination 1.9 KΩ+20 KΩ, the driving current is between 1.5 mA and 2.7 mA in various combination cases, and moreover, after 4 PSU power supplies are paralleled, the equivalent resistance is 5 KΩ which is much greater than the resistance value 1.9 KΩ of the motherboard resistor, which thereby satisfies the requirements of weak pull-up at the PSU power supplies and strong pull-up at the motherboard, so this pull-up resistance combination is the target pull-up resistance combination.

TABLE 1
Data comparison table of pull-up resistance combinations

| Motherboard | | | | | | |
|---|---|---|---|---|---|---|
| and power | | | Power | Power | | |
| supply pull-up | Number | Motherboard | supply | supply | | |
| resistance | of power | pull-up | pull-up | equivalent | Equivalent | Driving |
| combination | supplies | resistor/ | resistor/ | resistance/ | resistance/ | current/ |
| scheme | paralleled | kΩ | kΩ | kΩ | kΩ | mA |
| 4.7K + 20K | 1 | 4.7 | 20 | 20 | 3.806 | 0.7883 |
| | 2 | 4.7 | 20 | 10 | 3.197 | 0.9383 |
| | 3 | 4.7 | 20 | 6.67 | 2.757 | 1.0883 |
| | 4 | 4.7 | 20 | 5 | 2.423 | 1.2383 |
| 1.9K + 10K | 1 | 1.9 | 10 | 10 | 1.597 | 1.8789 |
| | 2 | 1.9 | 10 | 5 | 1.377 | 2.1789 |
| | 3 | 1.9 | 10 | 3.33 | 1.21 | 2.4789 |
| | 4 | 1.9 | 10 | 2.5 | 1.08 | 2.7789 |
| 4.7K + 10K | 1 | 4.7 | 10 | 10 | 3.197 | 0.9383 |
| | 2 | 4.7 | 10 | 5 | 2.423 | 1.2383 |
| | 3 | 4.7 | 10 | 3.33 | 1.95 | 1.5383 |
| | 4 | 4.7 | 10 | 2.5 | 1.632 | 1.8383 |
| 1.9K + 20K | 1 | 1.9 | 20 | 20 | 1.735 | 1.7289 |
| | 2 | 1.9 | 20 | 10 | 1.597 | 1.8789 |
| | 3 | 1.9 | 20 | 6.67 | 1.479 | 2.0289 |
| | 4 | 1.9 | 20 | 5 | 1.377 | 2.1789 |

Correspondingly, in the case where there is no target pull-up resistance combination in the pull-up resistance combinations in this embodiment, a prompt message may be output as shown in step 105 to prompt the user to re-input the pull-up resistance combination or the PSU pull-up resistor resistance value and the motherboard pull-up resistor resistance value.

Step 104: The target pull-up resistance combination is output.

It can be understood that the purpose of this step may be to make the user know the PSU pull-up resistor resistance value and the motherboard pull-up resistor resistance value that can be used in the SMBUS link by inputting the target pull-up resistance combinations, so that the user can set or select the resistance values of the pull-up resistors on the motherboard side and the PSU power supply side in the SMBUS link.

Specifically, taking the pull-up resistances of all the PSU power supplies in the SMBUS link being equal as an example, if the pull-up resistance of the motherboard is Rm, the pull-up resistance of the PSU power supply is Rs, the equivalent resistance of the link is Rp and the number of power supplies paralleled is n, the equivalent resistance of the link is calculated according to: Rp=Rs/n*Rm/(Rs/n+Rm)=Rs*Rm/(Rs+nRm). To facilitate the understanding, the following assumptions are made (Rm is 4.7, Rs is 4.7, and n is 4 at the maximum):

Assuming that the resistance value of the motherboard pull-up resistor is 1 (the pull-up capacity of the motherboard is 4.7 times stronger), Rp=Rs*Rm/(Rs+nRm)=Rs/(Rs+n), and when Rm is smaller as compared with Rs, the increase of n has no significant influence on Rp. Assuming that the resistance value of the motherboard pull-up resistor is equal to the power supply pull-up resistance, Rp=Rs*Rm/(Rs+nRm)=Rs/(1+n), and when Rm is larger as compared with Rs, the increase of n has no significant influence on Rp. Therefore, the larger the multiple between the resistance value of the motherboard pull-up resistor and the resistance value of the PSU power supply pull-up resistor, the smaller the influence on the equivalent resistance of the link when the PSU power supplies are paralleled, and the more constant the driving current.

That is to say, in this embodiment, when each of the pull-up resistance combinations includes one PSU pull-up resistor resistance value and one motherboard pull-up resistor resistance value, that is, when the resistance values of the pull-up resistors of all the PSU power supplies in the SMBUS link are equal, the target pull-up resistance combination with the largest multiple between the motherboard pull-up resistor resistance value and the PSU pull-up resistor resistance value may be output in this step to input the optimal target pull-up resistance combination, thereby ensuring that the driving current in the SMBUS link is as steady and constant as possible. That is to say, when each of the pull-up resistance combinations includes one PSU pull-up resistor resistance value and one motherboard pull-up resistor resistance value, this step may include: calculating a quotient of the PSU pull-up resistor resistance value and the motherboard pull-up resistor resistance value in each of the target pull-up resistance combinations, and outputting the target pull-up resistance combination corresponding to the quotient with the largest value.

Step 105: A prompt message is output.

The purpose of this step may be to prompt the user to re-input the pull-up resistance combination or the PSU pull-up resistor resistance value and the motherboard pull-up resistor resistance value by outputting the prompt message when there is no target pull-up resistance combination in the acquired pull-up resistance combinations, so that the process can return to step 101 to acquire new pull-up resistance combinations, which is convenient for the user to use.

In this embodiment of the disclosure, by determining whether there is the target pull-up resistance combination in the pull-up resistance combinations, the target pull-up resistance combination in the pull-up resistance combinations, which enables the driving capacity of the SMBUS link to be free from the influence of the number of PSU power supplies on the link, is output, thereby ensuring the driving capacity of the SMBUS link and improving the stability of the link.

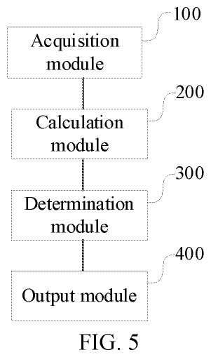

Referring to FIG. 5, FIG. 5 is a structural block diagram of an apparatus for determining pull-up resistance of a system management bus link according to an embodiment of the disclosure. The device may include:

an acquisition module 100, configured to acquire pull-up resistance combinations; where each of the pull-up resistance combinations includes a PSU pull-up resistor resistance value and one motherboard pull-up resistor resistance value;

a calculation module 200, configured to calculate an equivalent resistance range corresponding to a preset driving current range according to an acquired driving voltage; where the preset driving current range is greater than or equal to 0.5n and less than or equal to 0.9n, and n is a driving current threshold;

a determination module 300, configured to determine whether there is a target pull-up resistance combination in the pull-up resistance combinations; where a parallel equivalent resistance of any number of PSU pull-up resistors that is less than or equal to a number threshold and a motherboard pull-up resistor corresponding to each of the target pull-up resistance combinations is within the equivalent resistance range; and

an output module 400, configured to output, if there is the target pull-up resistance combination, the target pull-up resistance combination.

In this embodiment of the disclosure, the determination module 300 determines whether there is the target pull-up resistance combination in the pull-up resistance combinations, the target pull-up resistance combination in the pull-up resistance combinations, which enables the driving capacity of the SMBUS link to be free from the influence of the number of PSU power supplies on the link, is output, thereby ensuring the driving capacity of the SMBUS link and improving the stability of the link.

An embodiment of the disclosure further provides a device for determining pull-up resistance of a system management bus link, including: a memory, configured to store a computer program; and a processor, configured to implement the steps of any method for determining pull-up resistance of the system management bus link when executing the computer program.

The various embodiments in the specification are described in a progressive manner. Each embodiment focuses on differences from other embodiments, and for the same and similar parts between the embodiments, reference can be made to each other. Since the device and apparatus disclosed in the embodiments correspond to the method disclosed in the embodiment, the description is relatively simple, and for the relevant parts, reference can be made to the description of the method.

The steps of the method or algorithm described in conjunction with the embodiments disclosed herein may be directly implemented by hardware, a software module executed by a processor, or a combination thereof. The software module may be installed in a random access memory (RAM), an internal memory, a read only memory (ROM), an electrically programmable ROM, an electrically erasable programmable ROM, a register, a hard disk, a removable disk, a CD-ROM, or any other form of storage medium known in the art.

The system management bus link, and the method and apparatus for determining pull-up resistance thereof, and device provided by the disclosure have been described in detail above. Specific examples are used herein to explain the principles and implementations of the disclosure, and the description of the embodiments above is only used to help understand the method and core idea of the disclosure. It should be noted that those of ordinary skill in the art can make several improvements and modifications to the disclosure without departing from the principles of the disclosure, and such improvements and modifications also fall into the protection scope of the appended claims of the disclosure.

What is claimed is:

1. A system management bus link, comprising: a motherboard chip, a first pull-up resistor and a second pull-up resistor;
wherein first ends of the first pull-up resistor and the second pull-up resistor are connected to an output end of a driving voltage, a second end of the first pull-up resistor is connected to a clock end of the motherboard chip, a common end where the second end of the first pull-up resistor is connected to the clock end of the motherboard chip is configured to be connected to clock ends of a number of PSU power supply chips that is less than or equal to a number threshold, a second end of the second pull-up resistor is connected to a data end of the motherboard chip, and a common end where the second end of the second pull-up resistor is connected to the data end of the motherboard chip is configured to be connected to data ends of the PSU power supply chips; the clock end of each of the PSU power supply chips is connected to a second end of a corresponding third pull-up resistor in one-to-one correspondence, and the data end of each of the PSU power supply chips is connected to a second end of a corresponding fourth pull-up resistor in one-to-one correspondence; first ends of the third pull-up resistor and the fourth pull-up resistor are connected to the output end of the driving voltage;
the number threshold is a positive integer greater than 2; a resistance value of the first pull-up resistor satisfies that when the clock end of the motherboard chip is connected to the clock ends of any number of the PSU power supply chips, a driving current between the clock end of the motherboard chip and the clock end of each of the PSU power supply chips is greater than or equal to 0.5n and less than or equal to 0.9n; and a resistance value of the second pull-up resistor satisfies that when the data end of the motherboard chip is connected to the data ends of any number of the PSU power supply chips, a driving current between the data end of the motherboard chip and the data end of each of the PSU power supply chips is greater than or equal to 0.5n and less than or equal to 0.9n, wherein n is a driving current threshold.

2. The system management bus link according to claim 1, wherein the number threshold is 4.

3. The system management bus link according to claim 2, wherein when resistance values of the third pull-up resistors are all 20 KΩ, the resistance value of the first pull-up resistor is 1.9 KΩ.

4. The system management bus link according to claim 1, further comprising: a preset number of the PSU power supply chips, the third pull-up resistors and the fourth pull-up resistors;
wherein the preset number is less than or equal to the number threshold.

5. The system management bus link according to any one of claims 1 to 4, further comprising: a first MOS transistor, a second MOS transistor, a first resistor and a second resistor;
wherein the common end where the second end of the first pull-up resistor is connected to the clock end of the motherboard chip is connected to a drain of the first MOS transistor, a source of the first MOS transistor is configured to be connected to the clock end of the PSU power supply chip, a gate of the first MOS transistor is connected to a first end of the first resistor, and a second end of the first resistor is connected to the output end of the driving voltage; and the common end where the second end of the second pull-up resistor is connected to the data end of the motherboard chip is connected to a drain of the second MOS transistor, a source of the second MOS transistor is configured to be connected to the data end of the PSU power supply chip, a gate of the second MOS transistor is connected to a first end of the second resistor, and a second end of the second resistor is connected to the output end of the driving voltage.

6. A method for determining pull-up resistance of a system management bus link, comprising:
acquiring pull-up resistance combinations; wherein each of the pull-up resistance combinations comprises a PSU pull-up resistor resistance value and one motherboard pull-up resistor resistance value;
calculating an equivalent resistance range corresponding to a preset driving current range according to an acquired driving voltage; wherein the preset driving current range is greater than or equal to 0.5n and less than or equal to 0.9n, and n is a driving current threshold;
determining whether there is a target pull-up resistance combination in the pull-up resistance combinations; wherein a parallel equivalent resistance of any number of PSU pull-up resistors that is less than or equal to a number threshold and a motherboard pull-up resistor corresponding to each of the target pull-up resistance combinations is within the equivalent resistance range; and
outputting, if there is the target pull-up resistance combination, the target pull-up resistance combination.

7. The method for determining pull-up resistance of a system management bus link according to claim 6, wherein the motherboard pull-up resistor resistance value in each of the target pull-up resistance combinations is less than or equal to 0.5 times the equivalent resistance of the corresponding any number of PSU pull-up resistors that is less than or equal to the number threshold.

8. The method for determining pull-up resistance of a system management bus link according to claim 6, wherein when each of the pull-up resistance combinations comprises the PSU pull-up resistor resistance value and the motherboard pull-up resistor resistance value, outputting the target pull-up resistance combination comprises:
calculating a quotient of the PSU pull-up resistor resistance value and the motherboard pull-up resistor resistance value in each of the target pull-up resistance combinations, and outputting the target pull-up resistance combination corresponding to the quotient with the largest value.

9. An apparatus for determining pull-up resistance of a system management bus link, comprising:
an acquisition module, configured to acquire pull-up resistance combinations; wherein each of the pull-up resistance combinations comprises a PSU pull-up resistor resistance value and one motherboard pull-up resistor resistance value;
a calculation module, configured to calculate an equivalent resistance range corresponding to a preset driving current range according to an acquired driving voltage; wherein the preset driving current range is greater than or equal to 0.5n and less than or equal to 0.9n, and n is a driving current threshold;
a determination module, configured to determine whether there is a target pull-up resistance combination in the pull-up resistance combinations; wherein a parallel equivalent resistance of any number of PSU pull-up resistors that is less than or equal to a number threshold and a motherboard pull-up resistor corresponding to each of the target pull-up resistance combinations is within the equivalent resistance range; and
an output module, configured to output, if there is the target pull-up resistance combination, the target pull-up resistance combination.

10. A device for determining pull-up resistance of a system management bus link, comprising:
a memory, configured to store a computer program; and
a processor, configured to implement the steps of the pull-up resistance determination method of a system management bus link according to any one of claims 6-8 when executing the computer program.
